(19) United States
(12) Patent Application Publication
(10) Pub. No.: US 2018/0351479 A1
(43) Pub. Date: Dec. 6, 2018

(54) PRINTED MAGNETO-ELECTRIC ENERGY HARVESTER

(71) Applicant: The Board of Trustees of Western Michigan University, Kalamazoo, MI (US)

(72) Inventors: Amer Abdulmahdi Chlaihawi, Kalamazoo, MI (US); Massood Zandi Atashbar, Portage, MI (US); Bradley J. Bazuin, Kalamazoo, MI (US); Sepehr Emamian, Kalamazoo, MI (US); Binu Baby Narakathu, Portage, MI (US)

(21) Appl. No.: 15/968,256

(22) Filed: May 1, 2018

Related U.S. Application Data
(60) Provisional application No. 62/513,067, filed on May 31, 2017.

(51) Int. Cl. H02N 2/18; H01L 41/047; H01L 41/193; H01L 41/20; H01L 41/113; H01L 41/12; H01L 41/29; H01L 41/45; H01L 41/47

(52) U.S. Cl. CPC H02N 2/18; H01L 41/0477; H01L 41/193; H01L 41/20; H01L 41/47; H01L 41/125; H01L 41/29; H01L 41/45; H01L 41/113

(57) ABSTRACT

A magneto-electric energy harvester/generator includes a piezoelectric layer, a conductive layer disposed on a first side of the piezoelectric layer, and a layer of magnetic material disposed on a second side of the piezoelectric material. The device may be fabricated by screen printing polyvinylidene fluoride (PVDF) ink onto a flexible magnetic alloy substrate. Silver ink may then be screen printed onto the PVD material to form a conductive layer. The printed PVDF and silver layers may be cured by heating, and the device is then poled by applying an electric field.

### CROSS REFERENCE TO RELATED APPLICATION

This application claims the benefit of U.S. Provisional Application No. 62/513,067 filed on May 31, 2017, entitled, “PRINTED MAGNETO-ELECTRIC ENERGY HARVESTER,” the entire contents of which are incorporated herein by reference.

### BACKGROUND OF THE INVENTION

Advancements in manufacturing processes have enabled the development of miniaturized microelectronic devices with reduced power consumption for applications such as biomedical devices, portable electronics, and navigation systems. Energy harvesters in the electronic industry are devices or systems that capture ambient energy and convert it into electrical signals. These devices typically provide the power to charge, supplement, or replace batteries in electronic systems.

Among the different types of energy harvesters, magneto-electric effect based devices are known to generate relatively larger output voltages under low magnetic fields, along with higher power densities. Magneto-electric energy harvesters may be fabricated using silicon technology or by sandwiching piezoelectric/magnetostrictive laminate composites. Micro electromagnetic low level vibration energy harvesters have been fabricated based on MEMS technology.

Low frequency wireless powering of microsystems using piezoelectric/magnetostrictive laminate composites have also been developed. These devices may be fabricated on rigid substrates, using manufacturing processes that require clean room facilities and high temperatures. These processes may be relatively expensive and use glue for bonding.

A solution overcoming the drawbacks associated with the fabrication of energy harvesting devices would be beneficial.

### BRIEF SUMMARY OF THE INVENTION

One aspect of the present disclosure is the use of flexible and light weight functional materials for magneto-electric energy harvesters. Printing processes such as flexographic, gravure printing, inkjet printing and screen printing may be utilized to produce lightweight, cost efficient, biocompatible and flexible electronic devices. The use of printing processes enables a layer-on-layer device configuration that does not require adhesive bonding. For devices such as energy harvesters, which require mechanical flexibility, a layer-on-layer construction allows for bending with relatively uniform stress throughout device. Moreover, the use of printing processes has added advantages such as low manufacturing temperatures, reduced material usage, and less complex fabrication steps. The use of printing processes for printed and flexible magneto-electric energy harvesters may provide significant advantages in microelectronic devices.

These and other features, advantages, and objects of the present invention will be further understood and appreciated by those skilled in the art by reference to the following specification, claims, and appended drawings.

### BRIEF DESCRIPTION OF THE DRAWINGS

FIG. 1A is a schematic cross-sectional view of a magneto-electric energy harvester according to one aspect of the present disclosure;

FIG. 1B is a perspective view of a screen printed magneto-electric energy harvester/generator according to one aspect of the present disclosure;

FIG. 1C is a schematic side elevational view showing poling of a magneto-electric energy harvester;

FIG. 2A is a profilometry scan of a screen printed magneto-electric energy harvester/generator illustrating a total average thickness (ΔZ) of 35 μm;

FIG. 2B is a 3D profilometry scan of a screen printed magneto-electric energy harvester/generator illustrating a total average thickness (ΔZ) of 35 μm;

FIG. 3 is a schematic showing a test setup utilized to test a device according to one aspect of the present disclosure;

FIG. 4A is a chart showing DC output voltage of a printed magneto-electric energy harvester/generator as a function of varying load resistances at constant magnetic field of 92 Oe (oersted); and

FIG. 4B is a chart showing power (μW) generated by a printed magneto-electric energy harvester as a function of varying load resistances at constant magnetic field.

### DETAILED DESCRIPTION

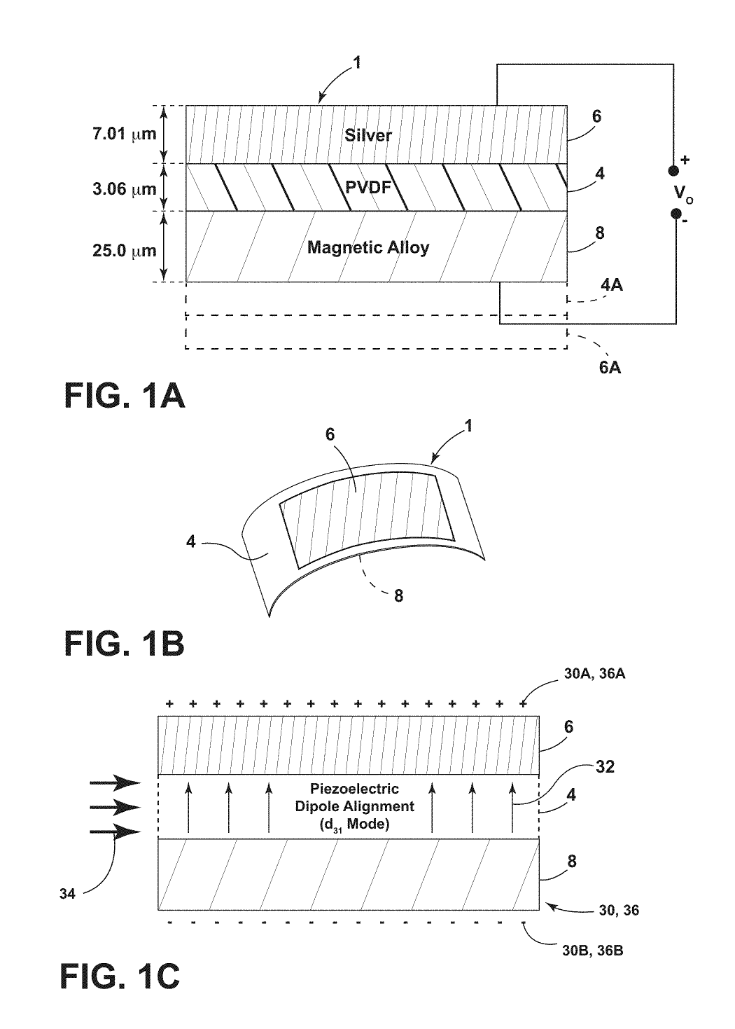

With reference to FIG. 1A, a magneto-electric energy harvester/generator 1 includes a polyvinylidene fluoride (PVDF) layer 4 that is disposed between a conductive metal (e.g. silver) layer 6 and a magnetic metal alloy layer 8. The magnetic metal alloy layer 8 may comprise an amorphous iron or cobalt based alloy available from Metglas Inc. of Conway, S.C. The PVDF layer 4 has a thickness of about 0.5 μm to about 100 μm, the conductive silver layer 6 has a thickness of about 0.5 μm to about 100 μm, and the layer 8 has a thickness of about 0.5 μm to about 1000 μm. It will be understood, however, that thicknesses outside of these ranges may be utilized, and the present disclosure is not limited to any particular thickness. The magneto-electric energy harvester/generator 1 may be fabricated by screen printing polyvinylidene fluoride (PVDF) ink, as a piezoelectric layer 4, on a flexible magnetic alloy substrate 8. Silver (Ag) ink may be screen printed to form a top electrode (conductive layer 6), on the printed PVDF layer 4. As discussed in more detail below, magneto-electric energy harvester/generator 1 may optionally include an additional PVDF layer 4A and an additional silver layer 6A that may be printed on an opposite side of magnetic alloy layer 8. As shown in FIG. 1B, the magneto-electric energy harvester/generator 1 may comprise a thin, flexible device. The magneto-electric energy harvester/generator 1 shown in FIG. 1B is a test unit (devices) fabricated according to the process described herein. As shown in FIG. 1B, the PVDF layer 4 may have larger overall dimensions than layers 6 and 8.

When a magnetic field is applied to the device 1, the magnetostrictive material (layer 8) induces mechanical strain in the piezoelectric material (PVDF layer 4). The piezoelectric material (PVDF layer 4) demonstrates the phenomenon of “piezoelectricity” which is the ability of the material to generate an electrical signal in response to an applied mechanical stress/strain. The piezoelectric effect is a reversible process. Thus, a mechanical stress/strain results from an applied electrical signal.

The top and bottom electrodes 6 and 8, respectively, are used to acquire the electric signal generated by the piezoelectric material (PVDF layer 4). Because the layer 8 is both conductive and magnetostrictive, it serves a dual purpose and is employed as the bottom electrode 8. As discussed above, the top electrode may comprise silver.

Device 1 can generate electricity by exposing device 1 to a magnetic field that magnetizes the lower layer 8, temporarily bending it and mechanically straining the piezoelectric layer 4. Flexing of device 1 due to application of force also generates electricity due to straining of the piezoelectric layer 4.

### EXAMPLE

A test unit/device 1 (e.g. FIG. 1B) was fabricated as discussed below. It will be understood that the present invention is not limited to this example.

### Chemicals and Materials

During fabrication of the test unit/device, a thin amorphous metal alloy (Metglas® 2605SA1), was used as the substrate 8. PVDF ink (SOLVENE® available from Solvay SA Corporation, Brussels, Belgium) was used for fabrication of the piezoelectric layer 4. Ag ink (Electrodag 479SS) (available from Henkel IP & Holding Gmbh Duesseldorf Fed Rep Germany), was used for the metallization of the top electrode 6 in the magneto-electric energy harvester/generator 1 test unit.

### Magneto-Electric Energy Harvester Fabrication

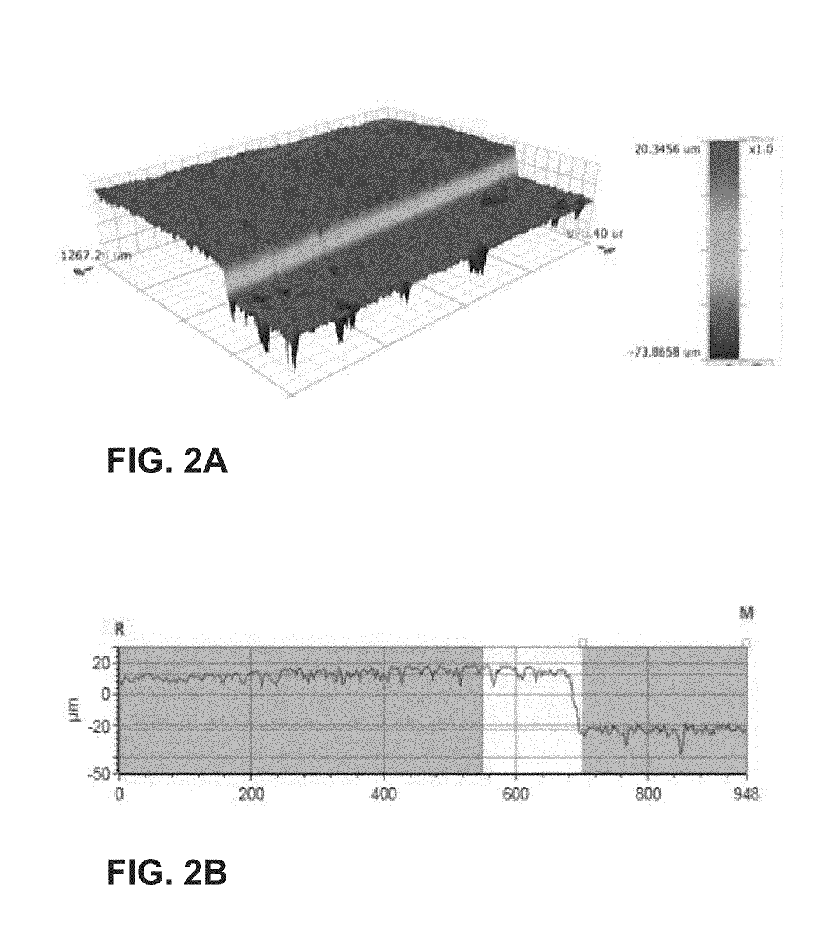

A magneto-electric energy harvester/generator 1 (FIGS. 1 and 2) according to one aspect of the present disclosure has overall device dimensions of 25×15×0.035 mm. As discussed above, the magneto-electric energy harvester/generator 1 may include three layers: a flexible magnetic alloy substrate 8, a piezoelectric PVDF layer 4, and a top Ag electrode 6. During fabrication of the test unit/device, the PVDF layer 4 and top electrode layer 6 were screen printed using a HMI MSP-485 high precision screen printer. The screen (Microscreen®) had 28 μm wire diameter, 22.5° angle and 12.7 μm thick MS-22 emulsion with stainless steel mesh count of 325. The screen printed PVDF layer 4 and Ag ink layer 6 were cured in a VWR® oven at 120° C. for 5 hours and for 20 minutes, respectively.

With reference to FIG. 1C, the piezoelectric PVDF layer 4 of the fabricated test device was poled by applying an electric field 30 of 80 V/μm for 3 hours. The positive and negative electric field directions/regions 30A, 30B, respectively, are shown schematically in FIG. 1C by the “+” and “−” symbols. Poling can be done in two directions: longitudinal (d₃₃) and transverse (d₃₁). The poling direction is selected such that that the piezoelectric dipoles (represented by arrows 32) are aligned perpendicular to the conductors 6 and 8 so that the maximum output voltage is achieved. In the present example, the poling was performed to align the piezoelectric dipoles in the transverse (d₃₁) direction as shown in FIG. 1C. After the applied electric field 30 is removed, the poled piezoelectric material 4 generates an electric field 36 with positive and negative directions/regions 36A, 36B, respectively. Electric field 36 is generally oriented in the same direction as applied electric field 30.

In use, a magnetic field 34 can be applied in one of two directions: longitudinal (H_{L}) or transverse (H_{T}) in order to generate electric power. The magnetic field direction is selected to be perpendicular to the electric field 36 so that a maximum magneto-electric voltage coefficient is achieved. Thus, the magnetic field 34 is preferably applied in a specific direction that is perpendicular to electric filed 36. In the example test device 1 described herein, the magnetic field 34 was applied in the longitudinal (H_{L}) direction.

Referring to FIGS. 2A and 2B, a total thickness of 35 μm was measured for the magneto-electric energy harvester/generator 1 using a Bruker Contour GT-K profilometer.

### Experimental Setup

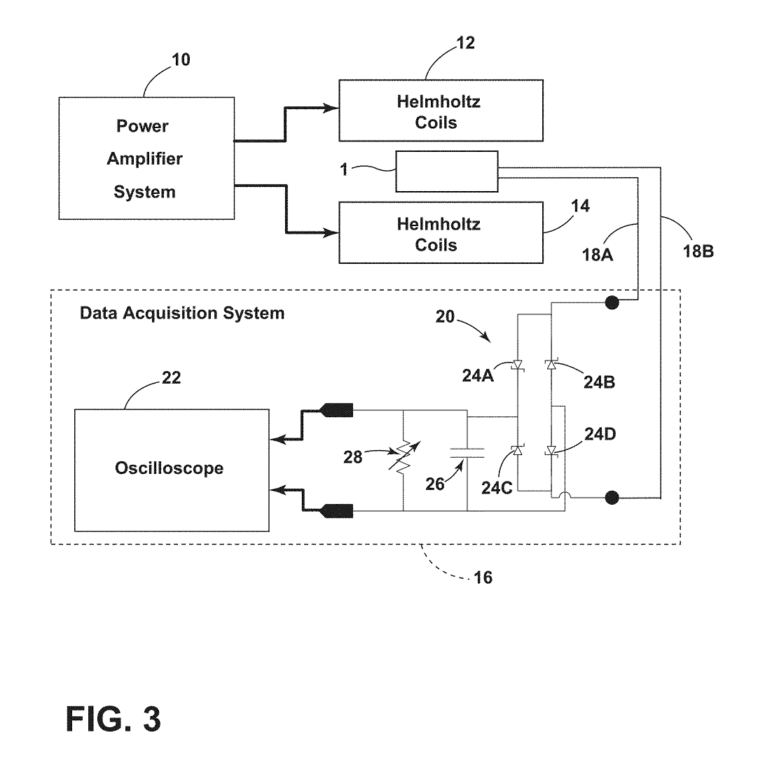

With reference to FIG. 3, the performance and capability of the fabricated (test) device 1 was investigated by measuring the DC output voltage for a frequency range of 20 Hz to 100 Hz, in steps of 20 Hz, and measuring the output power with load resistance varying from 4 kΩ to 2 MΩ. The test setup of FIG. 3 includes three primary components: a power amplifier system 10, a plurality of Helmholtz coils 12, 14 that provide a magnetic field, and a data acquisition system 16. The power amplifier system 10 includes two power supplies (R.S.R. Dual output DC power Supply PW-3032), a function generator (LG FG-8002), a power amplifier circuit (Operation Amplifier OPA549SG3, capacitor (0.01 μF), a resistor (6.8 kΩ; ¼ W and 1Ω; 10 W) and two Helmholtz coils 12, 14 (198 coil turns and 14 cm diameter). The power amplifier system 10 was used to drive the Helmholtz coils 12, 14 to supply a constant magnetic field 34 (FIG. 1C) of 92 Oe.

The test device 1 was positioned between the Helmholtz coils 12, 14 and it was connected to a bridge rectifying circuit 20. The data acquisition system 16 includes an oscilloscope 22 (Tektronix TDS5104B Digital Phosphor Oscilloscope), a full bridge rectifier with four Schottky diodes 24A-24C (1N5711), a capacitor 26 (10 μF) and a variable load resistance 28 (4 kΩ-2 MΩ). The response of the magneto-electric energy harvester 1 is converted to DC output voltage using the full bridge rectifier 20 and recorded in the oscilloscope 22.

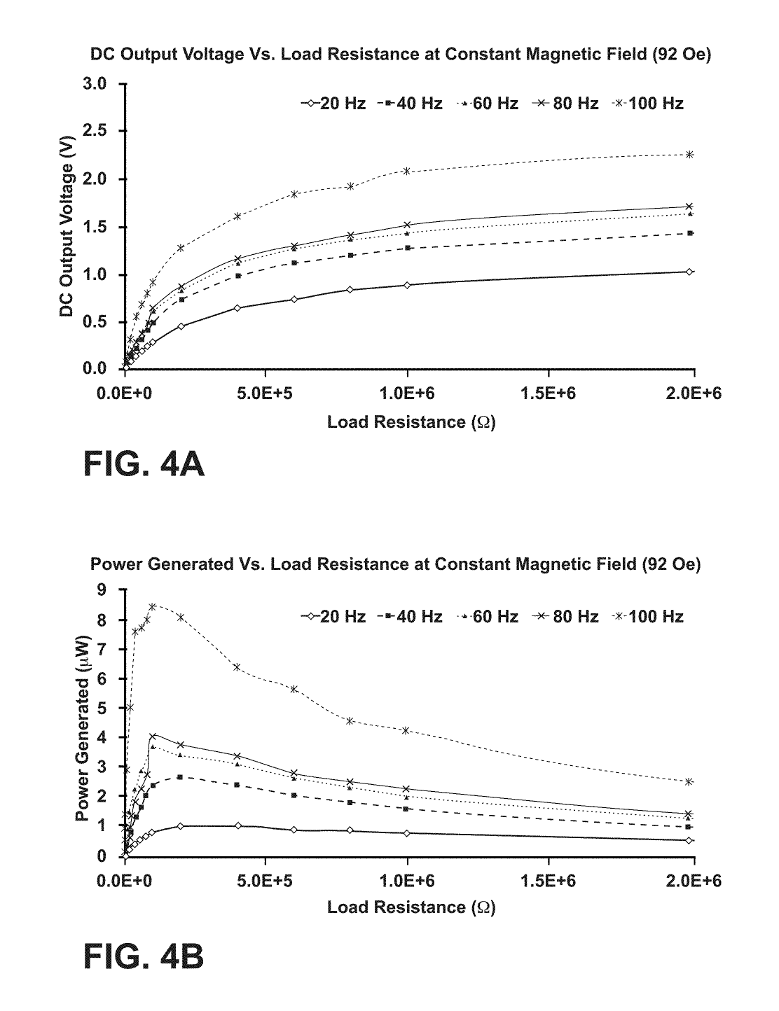

FIG. 4A shows the response of the printed magneto-electric energy harvester 1 towards varying load resistances at a constant magnetic field (92 Oersted). It was observed that the DC output voltages increased with increase in load resistances. In addition, the voltages also increased as the frequency was increased. For example, DC output voltages of 1.02 V, 1.42 V, 1.62 V, 1.71 V and 2.25 V were obtained for the 2 MΩ load resistance at frequencies of 20 Hz, 40 Hz, 60 Hz, 80 Hz and 100 Hz. This corresponds to a 39.21%, 58.82%, 67.64% and 120.56% change in DC output voltage for a frequency of 40 Hz, 60 Hz, 80 Hz and 100 Hz, respectively, when compared to the response for 20 Hz.

An energy harvesting transducer can be equivalent to a two-port network and the power generated on the load resistance may be mathematically calculated using equation (1):

Pₗ=V₀²Zₗ/(Z_{pz}+Zₗ)² (1)

Where Pₗ is the power generated on the load resistance, V₀ is the DC output voltage dissipated on the equivalent load, Z_{pz} is equivalent impedance of the magneto-electric energy harvester, and Zₗ is the load resistance. It is expected that the maximum power for a device will be achieved when Zₗ=Z_{pz}.

FIG. 4B shows the calculated power generated from the printed magneto-electric energy harvester 1 as a function of the varying load resistances at a constant magnetic field (92 Oersted). A right-skewed bell-curve was observed where the power increased and then decreased as the load resistance was increased from 4 kΩ to 2 MΩ. A maximum power of 1.03 μW, 2.67 μW, 3.68 μW, 4.03 μW and 8.41 μW was obtained at 400 kΩ, 200 kΩ, 100 kΩ, 100 kΩ and 100 kΩ load resistances for frequencies of 20 Hz, 40 Hz, 60 Hz, 80 Hz and 100 Hz, respectively. From the results, the maximum power generated was 8.41 μW for Zₗ=100 kΩ and 100 Hz. Therefore, the Z_{pz} of the magneto-electric energy harvester 1 is 100 kΩ. A power density of 639.59 μW/cm³ was calculated for the printed magneto-electric energy harvester 1.

The tests discussed above demonstrate that it is possible to successfully fabricate a printed magneto-electric energy harvester/generator 1 that is cost-efficient, light-weight and flexible using a printing process. The test device 1 (FIG. 1) was fabricated by screen printing PVDF ink, as a piezoelectric layer 4, on a magnetic alloy substrate 8. The top electrode (layer 6) was also screen printed using Ag ink on the printed PVDF layer 4. The capability of the printed magneto-electric energy harvester/generator 1 was investigated by measuring the DC output voltage (FIG. 4A) and maximum power (FIG. 4B) delivered at varying load resistances for a frequency range of 20 Hz to 100 Hz, in steps of 20 Hz. A maximum power of 8.41 μW was generated at a load resistance and frequency of 100 kΩ and 100 Hz, respectively. Thus, a power density of 639.59 μW/cm³ was achieved for the fabricated (test) magneto-electric energy harvester/generator 1. The test results show that an additive print manufacturing process can be utilized to fabricate a cost-efficient, light-weight and flexible magneto-electric energy harvester/generator 1.

Referring again to FIG. 1, according to another aspect of the present disclosure, electrodes 6 and 6A and PVDF layers 4 and 4A may be printed on opposite sides of the magnetic alloy substrate 8. For example, layers 4 and 6 may be printed on magnetic alloy substrate 8 as described above. The partially-fabricated device may then be rotated 180°, and layers 4A and 6A may then be printed on magnetic alloy substrate 8 in substantially the same manner as layers 4 and 6.

Various piezoelectric materials may be utilized to form layer 4, including Zinc oxide, (ZnO), Barium titanate (BaTiO3), Lead zirconate titanate (PZT), Nb doped PZT (PZTN), and Lead titanate (PhTiO₃). However, it will be understood that not all materials can be printed, and the fabrication process described herein may be modified if required for a particular material.

A magnetoelectric energy harvester 1 according to the present disclosure may be used for applications that have either a magnetic field or a mechanical stress/strain as an excitation source. The device 1 can be used to power devices in sensor networks which have low energy magnetic fields in the environment. Examples of applications include: (1) wireless charging of devices; and (2) monitoring infrastructure such as bridges and buildings. Based on mechanical stress/strain, device 1 can be used for powering wearable electronic devices by embedding device 1 in clothing, shoes, or the like such that the device 1 flexes and generates electrical power to operate a wearable electronic device. Device 1 may also be attached to skin of a user to generate electrical power to operate electronic devices upon flexing of device 1.

The invention claimed is:

1. A method of fabricating a flexible magneto-electric energy generating device, the method comprising:
printing a layer of piezoelectric material onto a substrate comprising a magnetic material;
printing a layer of a conductive material onto the piezoelectric material to form a flexible magneto-electric energy harvester device that is capable of generating electrical power when the piezoelectric material is strained upon exposure of the device to a magnetic field and/or upon application of a force to the device.

2. The method of claim 1, wherein:
the piezoelectric material is printed utilizing a screen printing process.

3. The method of claim 2, wherein:
the piezoelectric material comprises PVDF.

4. The method of claim 1, wherein:
the conductive material is printed utilizing a screen printing process.

5. The method of claim 4, wherein:
the conductive material comprises silver ink that solidifies to form a layer of silver.

6. The method of claim 1, wherein:
the magnetic material comprises a metal alloy.

7. The method of claim 6, wherein:
the metal alloy comprises an amorphous iron alloy.

8. The method of claim 1, wherein:
the magnetic material comprises a flexible sheet that is about 0.5 μm to about 1000 μm thick.

9. The method of claim 8, wherein:
the piezoelectric material is printed to form a solid layer that is about 0.5 μm to about 100 μm thick.

10. The method of claim 9, wherein:
the conductive material is printed to form a solid layer that is about 0.5 μm to about 100 μm thick.

11. The method of claim 1, wherein:
the PVDF is printed in liquid form; and including:
heating the printed PVDF to cure the PVDF to form solid layer of PVDF.

12. The method of claim 1, wherein:
the conductive material initially comprises a silver ink; and including:
heating the printed silver ink to form a solid layer of silver.

13. The method of claim 1, including:
applying an electric field to the device to pole the magnetic material.

14. The method of claim 1, including:
flexing the device to generate electrical energy.

15. A method of generating electrical power, the method comprising:
providing a flexible magneto-electric device having at least one layer of piezoelectric material, a layer of magnetic material disposed on a first side of the piezoelectric material, and a layer of conductive material disposed on a second side of the piezoelectric material;
connecting first and second conductors to the magnetic material and the conductive material, respectively; and
straining the piezoelectric material to generate electrical power across the first and second conductors.

16. The method of claim 15, including:
adhering the flexible magneto-electric device to a user's skin.

17. The method of claim 15, including:
adhering the flexible magneto-electric device to a surface of an object; and
causing the surface of the object to flex to thereby flex the flexible magneto-electric device.

18. The method of claim 15, including:
exposing the device to a magnetic field to strain the piezoelectric material.

19. A flexible magneto-electric device having at least one layer of piezoelectric material, a layer of magnetic material disposed on a first side of the piezoelectric material, and a layer of conductive material disposed on a second side of the piezoelectric material, such that the flexible magneto-electric device has a voltage difference across the magnetic material and the conductive material when the piezoelectric material is strained to thereby generate electrical power.

20. The flexible magneto-electric device of claim 19, wherein:
the piezoelectric material comprises a polymer;
the magnetic material comprises a metal alloy; and
the conductive material comprises a metal.

21. The flexible magneto-electric device of claim 19, wherein:
the flexible magneto-electric device is about 1.5 μm to about 1200 μm thick.
